(19) United States
(12) Patent Application Publication
(10) Pub. No.: US 2014/0060738 A1
(43) Pub. Date: Mar. 6, 2014

(54) APPARATUS FOR TREATING SUBSTRATE

(71) Applicant: Semes Co., Ltd., Cheonan-si (KR)

(72) Inventors: Hyung Joon KIM, Pyeongtaek-si (KR); Jae Min ROH, Pyeongtaek-si (KR)

(73) Assignee: SEMES CO., LTD., Cheonan-si (KR)

(21) Appl. No.: 14/012,213

(22) Filed: Aug. 28, 2013

(30) Foreign Application Priority Data
Aug. 31, 2012 (KR) 10-2012-0096777
Dec. 28, 2012 (KR) 10-2012-0156274

(51) Int. Cl. H01J 37/02

(52) U.S. Cl. CPC H01J 37/02
USPC 156/345.37; 156/345.48

(57) ABSTRACT

Provided is a substrate treating apparatus using plasma. A substrate treating apparatus includes a chamber having a treating space therein, a support member disposed in the chamber to support the substrate, a gas supply unit supplying a gas into the chamber, and a plasma source disposed on an upper portion of the camber, the plasma source including an antenna generating plasma from the gas supplied into the chamber, wherein the chamber includes a housing having an opened top surface, the housing having a treating space therein, and a dielectric substance assembly covering the opened top surface of the housing, and wherein the dielectric substance assembly includes a dielectric substance window and a reinforcement film having strength greater than that of the dielectric substance window.

### CROSS-REFERENCE TO RELATED APPLICATIONS

This U.S. non-provisional patent application claims priority under 35 U.S.C. §119 of Korean Patent Application Nos. 10-2012-0096777, filed on Aug. 31, 2012, and 10-2012-0156274, filed on Dec. 28, 2012, the entire contents of which are hereby incorporated by reference.

### BACKGROUND OF THE INVENTION

The present invention disclosed herein relates to an apparatus for treating a substrate, and more particularly, to a substrate treating apparatus using plasma.

To manufacturing semiconductor devices, various processes such as a photolithography process, an etching process, an ashing process, an ion injection process, a thin film deposition process, a cleaning process, and the like are performed to form a desired pattern on a substrate. Among these processes, the etching process removes a region selected from a layer that is formed on the substrate. The etching process may include wet etching and dry etching processes.

Among these, an etching apparatus using plasma is used for the dry etching process. In general, to generate plasma, an electromagnetic field is induced in an inner space of a chamber, and the electromagnetic filed excites a process gas provided in the camber into plasma state.

Plasma represents an ionized state of gas constituted by ions, electrons, and radicals. Plasma is generated at a very high temperature or by strong electric fields or radio frequency (RF) electromagnetic fields. In semiconductor device manufacturing processes, an etching process is performed by using plasma. The etching process is performed by allowing ion particles contained in the plasma to collide with the substrate.

In general, physical impacts may occur in the chamber due to plasma during the substrate treating process. Particularly, a dielectric assembly may be weak in strength to cause cracks during the substrate treating process. Also, since the inside of chamber is suddenly changed in temperature due to the generation of plasma, the dielectric assembly may be damaged. In addition, the dielectric assembly may be damaged due to a cleaning solution when the dielectric assembly is chemically cleaned after the substrate processing process.

### SUMMARY OF THE INVENTION

The present invention provides a substrate treating apparatus including a dielectric assembly having excellent strength and heat resistance in a substrate treating process using plasma.

The present invention also provides an substrate treating apparatus including a dielectric assembly having excellent chemical resistance and to prevent damage due to a cleaning solution during cleaning after the substrate treating process.

Embodiments of the present invention provide substrate treating apparatuses including: a chamber having a treating space therein; a support member disposed in the chamber to support the substrate; a gas supply unit supplying a gas into the chamber; and a plasma source disposed on an upper portion of the camber, the plasma source including an antenna generating plasma from the gas supplied into the chamber, wherein the chamber includes: a housing having an opened top surface, the housing having a treating space therein; and a dielectric substance assembly covering the opened top surface of the housing, and wherein the dielectric substance assembly includes a dielectric substance window and a reinforcement film having strength greater than that of the dielectric substance window.

In some embodiments, the reinforcement film may be attached to a top surface of the dielectric substance window.

In other embodiments, the reinforcement film may be provided as a multilayer.

In still other embodiments, at least one layer of the multilayer may be formed of a silicon material.

In even other embodiments, the dielectric substance assembly may further include a heating layer heating the dielectric substance window.

In yet other embodiments, the heating layer may be disposed above the dielectric substance window.

In further embodiments, the heating layer may be disposed on the reinforcement film, and the reinforcement film may be disposed on the dielectric substance window.

In still further embodiments, the dielectric substance assembly may further include a coating film having a shape surrounding top and side surfaces of the dielectric substance assembly.

In even further embodiments, the coating film may include Teflon.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a cross-sectional view of a substrate treating apparatus according to an embodiment of the present invention;

FIG. 2 is an exploded perspective view of a dielectric assembly of FIG. 1;

FIG. 3 is a cross-sectional view illustrating an example of the dielectric assembly of FIG. 2;

FIG. 4 is a cross-sectional view illustrating a modified example of the dielectric assembly of FIG. 3; and

FIG. 5 is a cross-sectional view illustrating another modified example of the dielectric assembly of FIG. 3.

### DETAILED DESCRIPTION OF PREFERRED EMBODIMENTS

The present invention may, however, be embodied in different forms and should not be constructed as limited to the embodiments set forth herein. Rather, these embodiments are provided so that this disclosure will be thorough and complete, and will fully convey the scope of the present invention to those skilled in the art. In the drawings, the thicknesses of layers and regions are exaggerated for clarity.

A substrate treating apparatus for etching a substrate using plasma according to an embodiment of the present invention will be described below. However, the present invention is not limited thereto. For example, the present invention may be applied to various apparatuses which can perform a process supplying the plasma into a chamber.

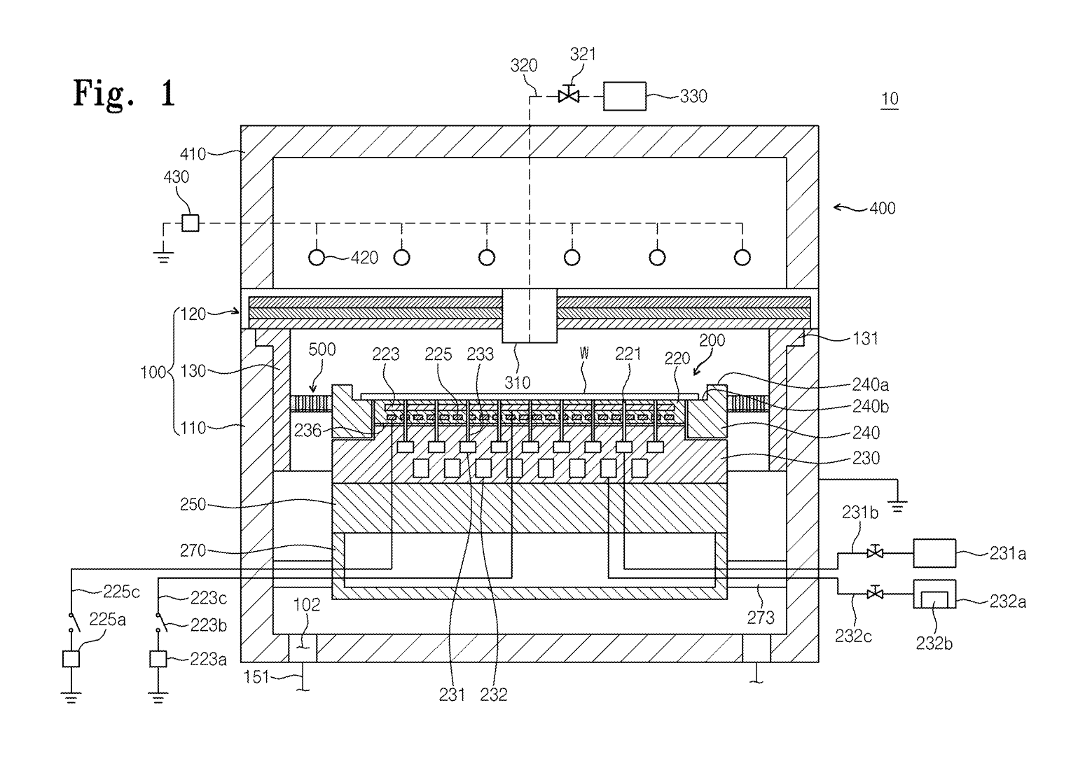

FIG. 1 is a cross-sectional view of a substrate treating apparatus according to an embodiment of the present invention.

Referring to FIG. 1, a substrate treating apparatus 10 treats a substrate W by using plasma. For example, the substrate treating apparatus 10 may perform an etching process on the substrate W. The substrate treating apparatus 10 includes a chamber 100, a support member 200, a gas supply unit 300, a plasma source 400, and a baffle unit 500.

The chamber 100 provides a space in which a substrate treating process is performed. The chamber 100 may include a housing 110, a dielectric substance assembly 120, and a liner 130.

The housing 110 has an inner space with a top surface opened. The inner space of the housing 110 provides a space in which the substrate treating process is performed. The housing 110 is formed of a metal. Alternatively, the housing 110 may be formed of an aluminum material. The housing 110 may be grounded. An exhaust hole 102 is defined in a bottom surface of the housing 110. The exhaust hole 102 is connected to an exhaust line 151. Reaction byproducts generated when the substrate treating process is performed and a gas staying within the housing 110 may be discharged to the outside through the exhaust line 151. Accordingly, the inner space of the housing 110 is decompressed at a predetermined pressure through the exhaust process.

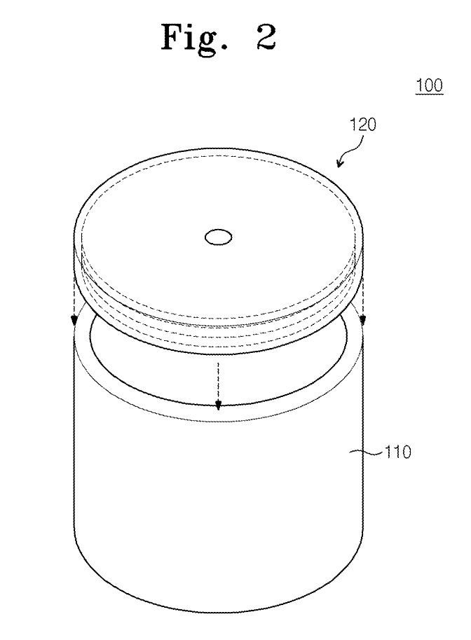

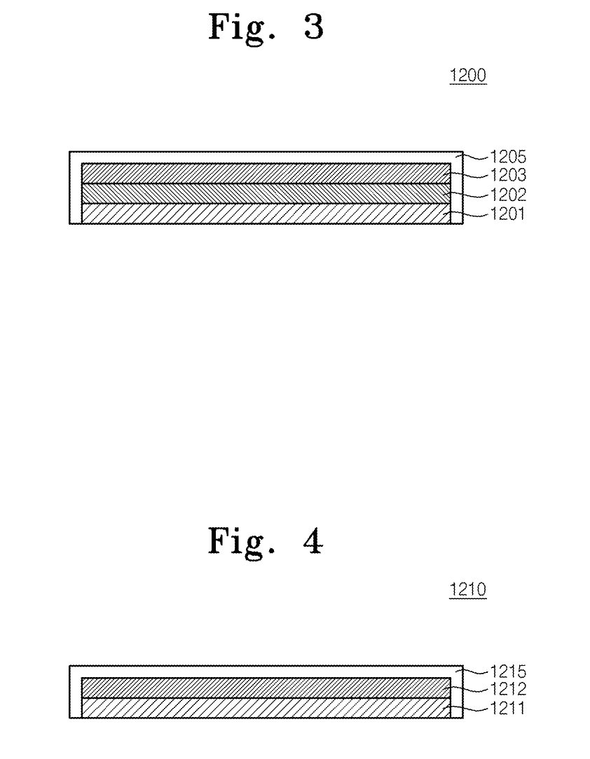

FIG. 2 is an exploded perspective view of a dielectric assembly of FIG. 1. FIG. 3 is a cross-sectional view of an example of the dielectric assembly of FIG. 2.

Referring to FIGS. 2 and 3, the dielectric substance assembly 120 covers the opened top surface of the housing 110. The dielectric substance assembly 120 has a plate shape to seal the inner space of the housing 110. The dielectric substance assembly 120 is separately provided.

A dielectric substance assembly 1200 according to an embodiment of the present invention includes a dielectric substance window 1201, a reinforcement film 1202, a heating layer 1203, and a coating film 1205. According to an embodiment, the dielectric substance assembly 1200 may a plate shape in which each of the dielectric substance window 1201, the reinforcement film 1202, the heating layer 1203, and the coating film 1205 has a predetermined thickness. Also, the dielectric substance window 1201, the reinforcement film 1202, and the heating layer 1203 may have the same sectional area to form respective layers. The coating film 1205 may have a shape surrounding top and side surfaces of a multilayer structure constituted by the dielectric substance window 1201, the reinforcement film 1202, and the heating layer 1203.

The dielectric substance window 1201 has the same diameter as the housing 110. According to an embodiment, the dielectric substance window 1201 may be formed of yttrium oxide (Y₂O₃) or aluminum oxide (Al₂O₃). The dielectric substance window 1201 may be disposed on a lower end of the dielectric substance assembly 120.

The reinforcement film 1202 is disposed on the dielectric substance window 1201. According to an embodiment, the reinforcement film 1202 may be attached to a top surface of the dielectric substance window 1201. The reinforcement film 1202 may be provided as a multilayer. At least one layer of the multilayer may be formed of a silicon material. The reinforcement film 1202 may be formed of a material having excellent strength. According to an embodiment, the reinforcement film 1202 may have strength greater than that of the dielectric substance window 1201.

The heating layer 1203 heats the dielectric substance window 1201. The heating layer 1203 may be disposed above the dielectric substance window 1201. Also, the heating layer 1203 may be disposed above the reinforcement film 1202. The heating layer 1203 may include heating members (not shown). The heating members (not shown) are disposed at a uniform distance in an entire region of the heating layer 1203. According to an embodiment, each of the heating members (not shown) may be provided in a spiral coil shape. Heat generated from the heating members (not shown) is transferred into an entire region of the dielectric substance assembly 1200.

The coating film 1205 is provided in a shape surrounding top and side surfaces of the dielectric substance assembly 1200. According to an embodiment, the coating film 1205 may be provided in a cylindrical shape having an opened lower portion. The coating film 1205 may include a material having excellent chemical resistance. According to an embodiment, the coating film 1205 may include Teflon.

In the above-descried exemplary embodiment of the present invention, the dielectric substance assembly 1200 includes the dielectric substance window 1201, the reinforcement film 1202, the heating layer 1203, and the coating film 1205. Alternatively, the dielectric substance assembly 1200 may do not include either or all of the heating layer 1203 and the coating film 1205. This will be described in a following modified example.

FIG. 4 is a cross-sectional view of a modified embodiment of the dielectric substance assembly of FIG. 3.

Referring to FIG. 4, a dielectric substance assembly 1210 includes a dielectric substance window 1211, a reinforcement film 1212, and a coating film 1215. When compared to the dielectric substance assembly 1200 of FIG. 3, the dielectric substance assembly 1210 may do not include the heating layer 1203. The dielectric substance assembly 1210 includes the reinforcement film 1212 having excellent strength. As a result, it may prevent the dielectric substance assembly 1210 from being damaged by an impact generated during the substrate treating process using plasma.

The dielectric substance assembly 1210 includes the coating film 1215. The coating film 1215 may be formed of a material having excellent chemical resistance. The coating film 1215 may prevent the dielectric substance window 1211 and the reinforcement film 1212, which are disposed in the inside of the coating film 1215, from being damaged in the cleaning process using the cleaning solution after the substrate treating process.

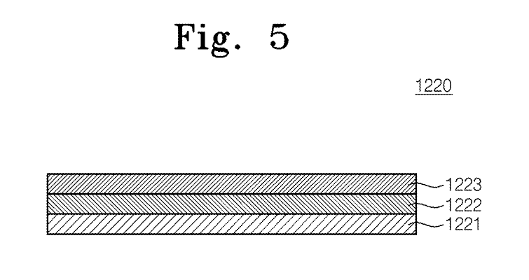

FIG. 5 is a cross-sectional view of another modified embodiment of the dielectric substance assembly of FIG. 3.

Referring to FIG. 5, a dielectric substance assembly 1220 includes a dielectric substance window 1221, a reinforcement film 1222, and a heating layer 1223. When compared to the dielectric substance assembly 1200 of FIG. 3, the dielectric substance assembly 1220 may do not include the coating film 1205. The dielectric substance window 1221, the reinforcement film 1222, and the heating layer 1223 may be disposed to form layers having the same sectional area, respectively.

The dielectric substance assembly 1220 includes the reinforcement film 1222 having excellent strength. As a result, it may prevent the dielectric substance assembly 1220 from being damaged an impact generated during the substrate treating process using plasma.

The dielectric substance assembly 1220 includes the heating layer 1223. During or before the substrate treating process using plasma, the heating layer 1223 heats the dielectric substance assembly 1220. As a result, it may prevent the dielectric substance assembly 1220 from being suddenly changed in temperature during the substrate treating process. Thus, the damage of the dielectric substance assembly 1220 due to the sudden change in temperature may be prevented.

Unlike the foregoing embodiment and the modified embodiments, the dielectric substance window, the reinforcement film, the heating layer, and coating film may be located at positions different from each other. For example, the heating layer may be disposed below the reinforcement film.

Referring again to FIG. 1, the liner 130 is disposed within the housing 110. The liner 130 has an inner space with opened top and bottom surfaces. The liner 130 may have a cylindrical shape. The liner 130 may have a radius corresponding to that of an inner surface of the housing 110. The liner 130 may be disposed along the inner surface of the housing 110. A support ring 131 is disposed on an upper end of the liner 130. The support ring 131 may be provided as a plate having a ring shape. The support ring 131 protrudes outward from the liner 130 along a circumference of the liner 130. The support ring 131 is disposed on an upper end of the housing 110 to support the liner 130. The liner 130 and the housing 110 may be formed of the same material. The liner 130 may be formed of an aluminum material. The liner 130 protects the inner surface of the housing 110. When a process gas is excited, arc discharge may occur within the chamber 100. The arc discharge may damage peripheral devices. The liner 130 may protect the inner surface of the housing 110 to prevent the inner surface of the housing 110 from being damaged by the arc discharge. Also, the liner 130 may prevent impurities generated during the substrate treating process from being deposited on an inner sidewall of the housing 110. The liner 130 may be inexpensive in manufacturing cost and easily replaced when compared to those of the housing 110. Thus, when the liner 130 is damaged by the arc discharge, a worker may replace the damaged liner 130 with a new liner 130.

The support member 200 is disposed within the housing 110. The support member 200 supports the substrate W. The support member 200 may include an electrostatic chuck 210 for absorbing the substrate W by using an electrostatic force. Alternatively, the support member 200 may support the substrate W through various methods such as mechanical clamping. Hereinafter, the support member 200 including the electrostatic chuck 210 will be described.

The support member 200 includes the electrostatic chuck 210, an insulation plate 250, and a lower cover 270. The support member 200 is spaced upward from the bottom surface of the housing 110 within the chamber 100.

The electrostatic chuck 210 includes a dielectric plate 220, an electrode 223, a heater 225, a support plate 230, and a focus ring 240.

The dielectric plate 220 is disposed on an upper end of the electrostatic chuck 210. The dielectric plate 220 has a circular shape and is formed of a dielectric substance. The substrate W is placed on a top surface of the dielectric plate 220. The top surface of the dielectric plate 220 has a radius less than that of the substrate W. Thus, the substrate W may have an edge area disposed outside the dielectric plate 220. A first supply passage 221 is defined in the dielectric plate 220. The first supply passage 221 is defined from the top surface up to a bottom surface of the dielectric plate 220. The first supply passage 221 may be provided in plurality. Also, the plurality of first supply passages 221 are spaced apart from each other. Each of the first supply passages 221 serves as a passage through which a thermal transfer medium is supplied to a bottom surface of the substrate W.

The lower electrode 223 and the heater 225 are buried in the dielectric plate 220. The lower electrode 223 is disposed above the heater 225. The lower electrode 223 is electrically connected to a first lower power source 223a. The first lower power source 223a may include a DC power source. A switch 223b is disposed between the lower electrode 223 and the first lower power source 223a. The lower electrode 223 may be electrically connected to the first lower power source 223a through an ON/OFF operation of the switch 223b. When the switch 223b is turned on, DC current is applied into the lower electrode 223. An electrostatic force may act between the lower electrode 223 and the substrate W by the current applied into the lower electrode 223. Thus, the substrate W may be absorbed to the dielectric plate 220 by the electrostatic force.

The heater 225 is electrically connected to a second lower power source 225a. The heater 225 may be resisted against current applied from the second lower power source 225a to generate heat. The generated heat may be transferred into the substrate W through the dielectric plate 220. The substrate W may be maintained at a predetermined temperature by the heat generated in the heater 225. The heater 225 includes a spiral coil.

The support plate 230 is disposed under the dielectric plate 220. A bottom surface of the dielectric plate 220 and a top surface of the support plate 230 may adhere to each other by using an adhesive 236. The support plate 230 may be formed of an aluminum material. The support plate 230 may have a stepped portion so that a central area of the top surface thereof is disposed at a height greater than that of an edge area thereof. The central area of the top surface of the support plate 230 has a surface area corresponding to that of the bottom surface of the dielectric plate 220 and adheres to the bottom surface of the dielectric plate 220. A first circulation passage 231, a second circulation passage 232, and a second supply passage 233 are defined in the support plate 230.

The first circulation passage 231 may be provided as a passage through which the thermal transfer medium is circulated. The first circulation passage 231 may be defined in a spiral shape within the support plate 230. Alternatively, the first circulation passage 231 may be provided so that ring-shaped passages having radii different from each other are concentrically disposed. In this case, the first circulation passages 231 may communicate with each other. The first circulation passages 231 may be defined at the same height.

The second circulation passage 232 may be provided as a passage through which a cooling fluid is circulated. The second circulation passage 232 may have defined in a spiral shape within the support plate 230. Alternatively, the second circulation passage 232 may be provided so that ring-shaped passages having radii different from each other are concentrically disposed. In this case, the second circulation passages 232 may communicate with each other. Each of the second circulation passage 232 may have a sectional area greater than that of each of the first circulation passages 231. The second circulation passages 232 may be defined at the same height. The second circulation passage 232 may be defined under the first circulation passage 231.

The second supply passage 233 extends upward from the first circulation passage 231 up to the top surface of the support plate 230. A second supply passage 243 may be provided in number corresponding to that of the first supply passages 221. The second supply passage 243 connects the first circulation passage 231 to the first supply passages 221.

The first circulation passage 231 is connected to a thermal transfer medium storage unit 231a through a thermal transfer medium supply line 231b. The thermal transfer medium is stored in the thermal transfer medium storage unit 231a. The thermal transfer medium includes an inert gas. According to an embodiment, the thermal transfer medium may include a helium (He) gas. The helium gas is supplied into the first circulation passage 231 through the thermal transfer medium supply line 231b. Then, the helium gas successively passes through the second supply passage 233 and the first supply passages 221 and then is supplied to the bottom surface of the substrate W. The helium gas may serve as a medium for transferring heat transferred from the plasma to the substrate W toward the electrostatic chuck 210.

The second circulation passage 232 is connected to a cooling fluid storage unit 232a through a cooling fluid supply line 232c. The cooling fluid is stored in the cooling fluid storage unit 232a. A cooler 232b may be disposed within the cooling fluid storage unit 232a. The cooler 232b cools the cooling fluid to a predetermined temperature. Alternatively, the cooler 232b may be disposed on the cooling fluid supply line 232c. The cooling fluid supplied into the second circulation passage 232 through the cooling fluid supply line 232c is circulated along the second circulation passage 232 to cool the support plate 230. The dielectric plate 220 and the substrate W may be cooled together while the support plate 230 is cooled to maintain the substrate W at a predetermined temperature.

The focus ring 240 is disposed on an edge area of the electrostatic chuck 210. The focus ring 240 has a ring shape and is disposed along a circumference of the dielectric plate 220. The focus ring 240 may have a stepped portion so that an outer portion 240a of a top surface thereof is disposed at a height greater than that of an inner portion 240b of the top surface thereof. The inner portion 240b of the top surface of the focus ring 240 is disposed at the same height as that of the dielectric plate 220. The inner portion 240b of the top surface of the focus ring 240 supports the edge area of the substrate W disposed outside the dielectric plate 220. The outer portion 240a of the focus ring 240 surrounds the edge area of the substrate W. The focus ring 240 may focus the plasma into a region facing the substrate W within the chamber 100.

The insulation plate 250 is disposed under the support plate 230. The insulation plate 250 has a sectional area corresponding to that of the support plate 230. The insulation plate 250 is disposed between the support plate 230 and the lower cover 270. The insulation plate 250 is formed of an insulation material to electrically insulate the support plate 230 from the lower cover 270.

The lower cover 270 is disposed on a lower end of the support member 200. The lower cover 270 is spaced upward from the bottom surface of the housing 110. The lower cover 270 has an inner space with an opened top surface. The top surface of the lower cover 270 is covered by the insulation plate 250. Thus, an external radius in a sectional area of the lower cover 270 may have the same length as that of the insulation plate 250. A lift pin module (not shown) for moving the carried substrate W from an external carrying member to the electrostatic chuck 210 may be disposed in the inner space of the lower cover 270.

The lower cover 270 includes a connection member 273. The connection member 273 connects an outer surface of the lower cover 270 to the inner sidewall of the housing 110. The connection member 273 may be provided in plurality. The plurality of connection members 273 may be disposed on the outer surface of the lower cover 270 at a predetermined distance. The connection members 273 support the support member 200 inside the chamber 100. Also, the connection members 273 may be connected to the inner sidewall of the housing 110 to allow the lower cover to be electrically grounded. A first power line 223c connected to the first lower power source 223a, a second power line 225c connected to the second lower power source 225a, the thermal transfer medium supply line 231b connected to the thermal transfer medium storage unit 231a, and the cooling fluid supply line 232c connected to the cooling fluid storage unit 232a may extend into the lower cover 270 through inner spaces of the connection members 273, respectively.

The gas supply unit 300 supplies the process gas into the chamber 100. The gas supply unit 300 includes a gas supply nozzle 310, a gas supply line 320, and a gas storage unit 330. The gas supply nozzle 310 is disposed at a central portion of the dielectric substance assembly 120. An injection hole is defined in a bottom surface of the gas supply nozzle 310. The injection hole is defined in a lower portion of the dielectric substance assembly 120 to supply the process gas into the chamber 100. The gas supply line 320 connects the gas supply nozzle 310 to the gas storage unit 330. The gas supply line 320 supplies the process gas stored in the gas storage unit 330 into the gas supply nozzle 310. A valve 321 is disposed in the gas supply line 320. The valve 321 opens or closes the gas supply line 320 to adjust a flow rate of the process gas supplied through the gas supply line 320.

The plasma source 400 excites the process gas within the chamber 100 into a plasma state. An inductively coupled plasma (ICP) source may be used as the plasma source 400. The plasma source 400 includes an antenna chamber 410, an antenna 420, and a plasma power source 430. The antenna chamber 410 has a cylindrical shape with an opened lower side. The antenna chamber 410 has an inner space. The antenna chamber 410 may have a diameter corresponding to that of the chamber 100. The antenna chamber 410 may have a lower end detachably disposed on the dielectric substance assembly 120. The antenna 420 is disposed inside the antenna chamber 410. The antenna 420 may be provided as a spiral coil that is wound several times. The antenna 420 is connected to the plasma power source 430. The antenna 420 receives a power from the plasma power source 430. The plasma power source 430 may be disposed outside the chamber 100. The antenna 420 to which the power is applied may generate electromagnetic fields in a processing space of the chamber 100. The process gas is excited into the plasma state by the electromagnetic fields.

The baffle unit 500 is disposed between the inner sidewall of the housing 110 and the support member 200. The baffle unit 500 includes a baffle 510 having through holes 511. The baffle 510 may have an annular ring shape. The plurality of through holes 511 are defined in the baffle 510. The process gas supplied into the housing 110 is exhausted through the exhaust hole 102 via the through holes 511 of the baffle 510. The process gas may be controlled in flow according to shapes of the baffle 510 and each of the through holes 511.

Hereinafter, a process of treating a substrate by using the substrate treating apparatus of FIG. 1 will be described.

When a substrate W is placed on a support member 200, DC current is applied into a lower electrode 223 from a first lower power source 223a. An electrostatic force may act between the lower electrode 223 and the substrate W by the DC current applied into the lower electrode 223. Thus, the substrate W may be absorbed to an electrostatic chuck 210 by the electrostatic force.

When the substrate W is absorbed on the electrostatic chuck 210, a process gas is supplied into a housing 110 through a gas supply nozzle 310. Also, a high-frequency power generated in a plasma power source 430 is applied into the housing 110 through an antenna 420. The applied high-frequency power excites the process gas staying in the housing 110. The excited process gas is provided onto the substrate W to treat the substrate W. An etching process may be performed by using the excited process gas.

In the substrate treating process using plasma, a physical impact may occur in a chamber 100, i.e., a dielectric substance assembly 120 due to plasma while the plasma is generated, and the substrate W is treated by using the generated plasma to cause cracks. Also, while the plasma is generated, and then the substrate is treated using the plasma, the inside of the chamber may be suddenly changed in temperature. Since the temperature is suddenly changed in the substrate treating process, the dielectric substance assembly 120 may be cracked.

According to an embodiment of the present invention, the dielectric substance assembly 1200 further includes the reinforcement film 1202 having excellent strength on the dielectric substance window 1201. As a result, it may prevent the dielectric substance assembly 1200 from being cracked and damaged due to the physical impact generated in the substrate treating process using the plasma.

Also, according to an embodiment of the present invention, the dielectric substance assembly 1200 includes the heating layer 1203. Before or during the substrate treating process, the heating layer 1203 heats the dielectric substance assembly 1200. The heated dielectric substance assembly 1200 may not be suddenly changed in temperature due to the heating layer 1203. The heating layer 1203 may adjust a temperature of the dielectric substance assembly 1200 to prevent the dielectric substance assembly 120 from being suddenly changed in temperature. As a result, it may prevent the dielectric substance assembly 1200 from being damaged due to sudden temperature change within the chamber 100.

The dielectric substance assembly 1200 is separably provided. After the substrate treating process, the dielectric substance assembly 1200 may be separated to clean particles and impurities that are deposited during the treating process. Here, the dielectric substance assembly 1200 may be damaged by the cleaning solution.

According to an embodiment of the present invention, the dielectric substance assembly 1200 includes the coating film 1205. The coating film 1205 may include the Teflon having the excellent chemical resistance. As a result, it may prevent the dielectric substance assembly 1200 from being damaged by the cleaning solution.

According to the embodiment of the present invention, the substrate treating apparatus including the dielectric substance assembly having the excellent strength and heat resistance may be provided.

Also, according to the embodiment of the present invention, the substrate treating apparatus including the dielectric substance assembly having the excellent chemical resistance may be provided.

The feature of the present invention is not limited to the aforesaid, but other features not described herein will be clearly understood by those skilled in the art from this specification and the accompanying drawings.

If a person of ordinary skill in the art to which this invention pertains without departing from the essential characteristics of the present invention in the range described above, is only the spirit of the present invention have been described for illustrative purposes, various modifications, additions and substitutions are possible. Therefore, to explain the embodiments disclosed in the present invention is not limited to the technical idea of the present invention, and are not limited by this embodiment of the present invention, the spirit of the scope The scope of protection of the present disclosure, all the technical idea, within the scope of its equivalent shall be construed by the following claims should be construed as being included in the scope of the present disclosure.

What is claimed is:

1. A substrate treating apparatus comprising:
a chamber having a treating space therein;
a support member disposed in the chamber to support the substrate;
a gas supply unit supplying a gas into the chamber; and
a plasma source disposed on an upper portion of the camber, the plasma source comprising an antenna generating plasma from the gas supplied into the chamber,
wherein the chamber comprises:
a housing having an opened top surface, the housing having a treating space therein; and
a dielectric substance assembly covering the opened top surface of the housing, and
wherein the dielectric substance assembly comprises a dielectric substance window and a reinforcement film having strength greater than that of the dielectric substance window.

2. The substrate treating apparatus of claim 1, wherein the reinforcement film is attached to a top surface of the dielectric substance window.

3. The substrate treating apparatus of claim 2, wherein the reinforcement film is provided as a multilayer.

4. The substrate treating apparatus of claim 3, wherein at least one layer of the multilayer is formed of a silicon material.

5. The substrate treating apparatus of claim 1, wherein the dielectric substance assembly further comprises a heating layer heating the dielectric substance window.

6. The substrate treating apparatus of claim 5, wherein the heating layer is disposed above the dielectric substance window.

7. The substrate treating apparatus of claim 6, wherein the heating layer is disposed on the reinforcement film, and
the reinforcement film is disposed on the dielectric substance window.

8. The substrate treating apparatus of claim 1, wherein the dielectric substance assembly further comprises a coating film having a shape surrounding top and side surfaces of the dielectric substance assembly.

9. The substrate treating apparatus of claim 8, wherein the coating film comprises Teflon.

10. The substrate treating apparatus of claim 7, wherein the dielectric substance assembly further comprises a coating film having a shape surrounding top and side surfaces of the dielectric substance assembly,
wherein the coating film comprises Teflon.
